(19) United States
(12) Patent Application Publication
(10) Pub. No.: US 2009/0174078 A1
(43) Pub. Date: Jul. 9, 2009

(54) Semiconductor device and method of manufacturing the same

(75) Inventors: Hyeck-Jin Jeong, Cheonan-si (KR); Seon-Ju Oh, Cheonan-si (KR); Yong-Ki Park, Cheonan-si (KR); Heui-Seog Kim, Cheonan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/318,635

(22) Filed: Jan. 5, 2009

(30) Foreign Application Priority Data
Jan. 3, 2008 (KR) 10-2008-0000820

(51) Int. Cl. H01L 23/522

(52) U.S. Cl. 257/768; 257/E23.142

(57) ABSTRACT

Provided is a semiconductor device and method of manufacturing the same. The semiconductor device may include a base material and a compound layer on the base material including a mixture of a non-adhesive organic material and a non-oxidizing metal material.

### PRIORITY STATEMENT

This U.S. non-provisional patent application claims priority under 35 U.S.C. §119 to Korean Patent Application No. 10-2008-0000820, filed on Jan. 3, 2008, in the Korean Intellectual Property Office (KIPO), the entire contents of which are incorporated herein by reference.

### BACKGROUND

1. Field

Example embodiments relate to a semiconductor device and method of manufacturing the same.

2. Description of the Related Art

A semiconductor device, in order to be capable of performing all the functions of a completed semiconductor device package, is formed by being subjected to a multitude of processes. These processes can be largely categorized into semiconductor wafer production, semiconductor device fabrication (FAB), assembly, and test procedures.

Testing is performed to check the semiconductor device's reliability and to determine if a completed semiconductor device is defective. Test procedures may include an electrical die sort (EDS) test of a wafer, and an EDS test of a semiconductor device package. Test procedures may include an electrical signal characteristics test in which all the input/output terminals of the semiconductor device are connected to a test signal generating circuit (that is, to a semiconductor test apparatus), to check whether the semiconductor device functions properly and for the presence of shorts in the device. A test of a semiconductor device must be performed precisely. Furthermore, because a semiconductor test apparatus is used to test a relatively large number of semiconductor devices, the semiconductor test apparatus must be highly reliable. The level of precision and reliability of a test procedure can affect the quality of finished semiconductor devices.

### SUMMARY

Example embodiments provide a semiconductor device and method of manufacturing the same, which allow for preciseness and reliability during testing.

According to example embodiments, a semiconductor device may include a base material and a compound layer on the base material including a mixture of a non-adhesive organic material and a non-oxidizing metal material.

In example embodiments, the non-oxidizing metal material may include at least one of gold (Au), silver (Ag), platinum (Pt), palladium (Pd), iridium (Ir), osmium (Os), rhodium (Rh), and ruthenium (Ru). The organic material may include a fluorine resin-based organic material. The organic material may include at least one of polytetrafluoroethylen (PTFE), a tetrafluorethylen-perfluoralkylvinylether (PFA) copolymer, polyfluorovinyliden (PVDF), polyethylene (PE), polypropylene (PP), polychlorotrifluoroethylene (PCTFE), a tetrafluorethylene-hexafluorpropylene (FEP) copolymer, and an ethylene-tetrafluorethylene (ETFE) copolymer.

In example embodiments, the base material may include a contact region configured to electrically connect to an input/output terminal of a semiconductor device to be tested, and the compound layer may cover the base material at the contact region. In example embodiments, the base material may include at least one of beryllium copper (BeCu), tungsten (W), and ruthenium tungsten (ReW).

In example embodiments, the semiconductor device may further include a bonding layer between the base material and the compound layer to bond the base material and the compound layer. The bonding layer may include a nickel plating layer or a copper plating layer. In example embodiments, the base material may have a bar-type configuration, and may include one or a plurality of sharp heads. The bar-type configuration may include a bent bar-type configuration. In example embodiments, the base material may include a planarized contact surface. In example embodiments, the base material may include an uneven contact surface. In example embodiments, the base material may have a cantilevered shape with one end bent at a given angle.

According to example embodiments, a method of manufacturing a semiconductor device may include providing a base material and forming a compound layer via electroplating and sputtering on the base material including a mixture of a non-adhesive organic material and a non-oxidizing metal material.

In example embodiments, the compound layer may be formed via electroplating and sputtering. In example embodiments, forming the compound layer may include forming a gold plating layer made of gold particles via electroplating to cover the base material, and performing a sputtering process to form a compound layer. In example embodiments, the base material may be a Teflon base material, and the method may further include providing Teflon particles on the gold plating layer. In example embodiments, providing the base material may include providing the base material including a contact region configured to electrically connect to an input/output terminal of a semiconductor device to be tested, wherein the compound layer may cover the base material in the contact region.

In example embodiments, the method may further include forming a bonding layer between the base material and the compound layer to bond the base material and the compound layer. In example embodiments, the bonding layer may be formed via electroplating. In example embodiments, providing the base material may include providing the base material having either a bar-type configuration and including one or a plurality of sharp heads, a bent bar-type configuration, a planarized contact surface, an uneven contact surface, or a cantilevered shape with one end bent at a given angle.

### BRIEF DESCRIPTION OF THE FIGURES

Example embodiments will be more clearly understood from the following detailed description taken in conjunction with the accompanying drawings. FIGS. 1-6 represent non-limiting, example embodiments as described herein.

FIG. 1 is a sectional view of a semiconductor device according to example embodiments;

FIG. 2 is a sectional view illustrating a method of forming a semiconductor device according to example embodiments; and

FIGS. 3-6 are sectional views illustrating semiconductor devices to be tested according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will be described below in more detail with reference to the accompanying drawings. Example embodiments may, however, be embodied in different forms and should not be construed as limited to the embodiments set forth herein. Rather, these embodiments are provided so that this disclosure will be thorough and complete, and will fully convey the scope of example embodiments to those skilled in the art. Like reference numerals refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

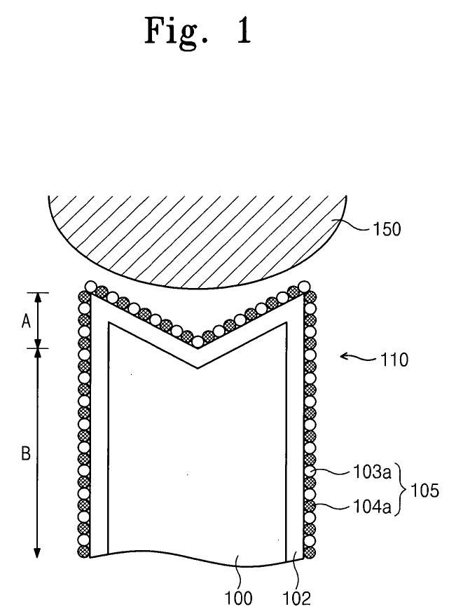

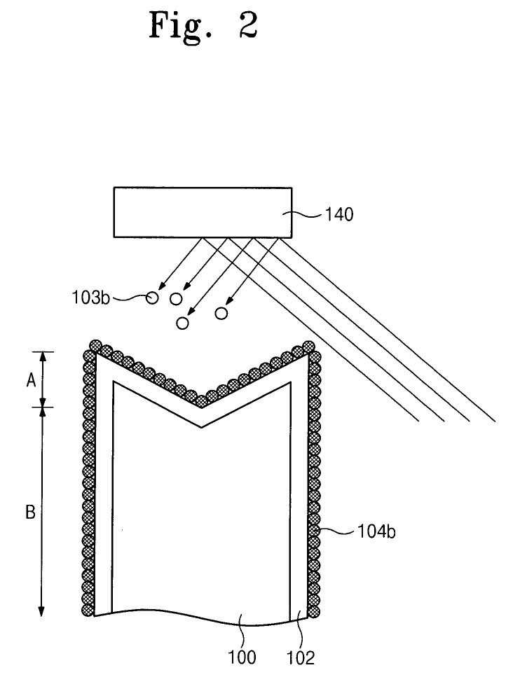

FIG. 1 is a sectional view of a semiconductor device according to example embodiments, and FIG. 2 is a sectional view illustrating a method of forming a semiconductor device according to example embodiments.

Referring to FIG. 1, a contact terminal 10 of a semiconductor device according to example embodiments may include a base material 100 and a compound layer 105. The base material 100 may include at least one of beryllium copper (BeCu), tungsten (W), and ruthenium tungsten (ReW). A bonding layer 102 may be interposed between the base material 100 and the compound layer 105. A contact region (A) is designated as a region contacting an input/output terminal 150 of a semiconductor device for applying an electrical signal to a semiconductor device to be tested. A noncontact region (B) is designated as a region functioning as a passage for applying an electrical signal to the semiconductor device. The input/output terminal 150 of the semiconductor device may, for example, be an input/output terminal of the semiconductor device or an input/output terminal of a semiconductor device package including the semiconductor device.

The compound layer 105 may cover the base material 100. The compound layer 105 may be formed on the base material 100 in the contact region (A). The compound layer 105 may cover a portion in the contact region (A), or the compound layer 105 may cover the entirety of the contact region (A). The structure of the compound layer 105 may not be those illustrated in the diagrams (which are illustrated as such for the sake of convenience). The compound layer 105 may include a non-adhesive organic material 103a and a non-oxidizing metal material 104a. The organic material 103a may include a fluorine resin-based organic material. Non-adhesiveness refers to the property of not easily adhering to another material.

The organic material 103a may include, for example, at least one of polytetrafluoroethylen (PTFE, hereinafter referred to as Teflon), a tetrafluorethylen-perfluoralkylvinylether (PFA) copolymer, polyfluorovinyliden (PVDF), polyethylene (PE), polypropylene (PP), polychlorotrifluoroethylene (PCTFE), a tetrafluorethylene-hexafluorpropylene (FEP) copolymer, and an ethylene-tetrafluorethylene (ETFE) copolymer.

The contact terminal 110 of the semiconductor device must contact input/output terminals 150 of a relatively large number of semiconductor devices to be tested. The input/output terminal 150 may include tin (Sn) or tin (Sn) and lead (Pb). The organic material 103a included in the compound layer 105 of the contact terminal 110 may function to prevent or reduce the tin (Sn) or tin (Sn) and lead (Pb) included in an input/output terminal 150 from readily adhering to the contact terminal 110 when in contact with the input/output terminal 150 of a semiconductor device. Accordingly, the adherence of tin (Sn) or tin (Sn) and lead (Pb) to the contact terminal 110 from repeated contact with the input/output terminals 150 of semiconductor devices may be prevented or reduced. Thus, the formation of an oxide covering layer, for example, a tin oxide layer (SnO₂), on the contact terminal 110 may be prevented or reduced. As a result, contact resistance between the contact terminal 110 and the repeatedly contacted input/output terminals 150 of semiconductor devices (for testing) may be uniformly maintained.

According to example embodiments, electrical signals of test procedures may be applied uniformly to many switched semiconductor devices, so that reliability of testing may be improved and yield and quality of semiconductor devices may be increased. Because the organic material 103a mixed in the compound layer 105 prevents or reduces tin (Sn) or tin (Sn) and lead (Pb) from readily adhering to the contact terminal 110, service and maintenance of a contact terminal 110 of a semiconductor device may be made easier. Accordingly, the service life of a semiconductor device may be extended.

The metal material 104a may include at least one of gold (Au), silver (Ag), platinum (Pt), palladium (Pd), iridium (Ir), osmium (Os), rhodium (Rh), and ruthenium (Ru). According to example embodiments, the compound layer 105 may include the non-oxidizing metal material 104a to prevent or reduce surface oxidation of the contact terminal 110 of the semiconductor device. Also, the non-oxidizing metal material 104a may have favorable conductivity which may increase conductivity of the contact terminal 110. Accordingly, electrical signals in test procedures may be precisely applied to semiconductor devices, thereby increasing precision in testing.

Referring to FIG. 2, the compound layer 105 may be formed using electroplating and sputtering processes. For example, a gold plating layer may be formed of gold particles 104b through electroplating to cover the base material 100. After the gold plating layer is formed, a sputtering process may be performed to form a compound layer. Using a Teflon base material 140 as a target, Teflon particles 103b may be provided on the gold plating layer to form a compound layer similar to that in FIG. 1, formed of a mixture of Teflon particles 103b and gold particles 104b.

A bonding layer 102 may be interposed between the base material 100 and the compound layer 105. The bonding layer 102 may be a plated layer that facilitates adhering of other metals to the surface of the base material 100, and may provide improved electrical conductivity. The bonding layer 102 may include, for example, a nickel plating layer or a copper plating layer. The bonding layer 102 may be formed through electroplating.

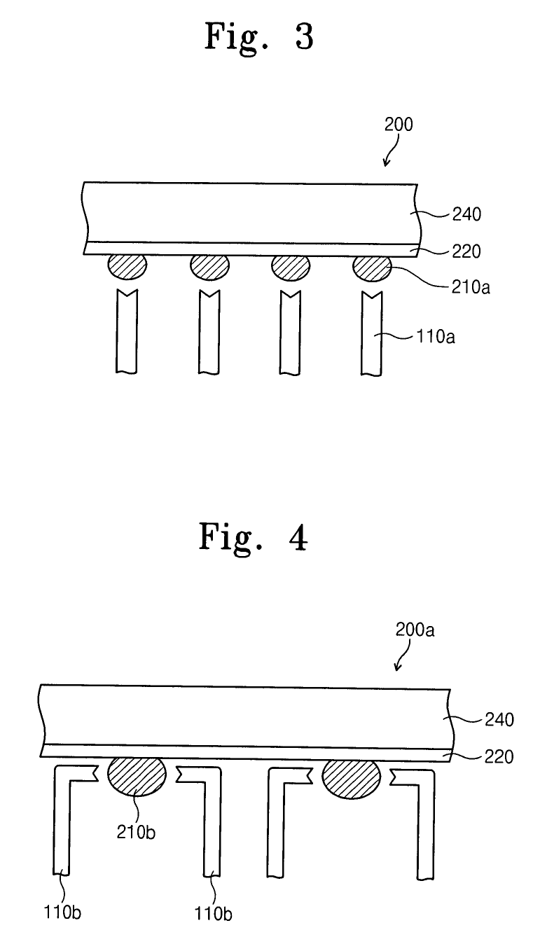

FIGS. 3-6 are sectional views illustrating a semiconductor device to be tested according to example embodiments. Depending on the semiconductor device to be tested, the external shapes and numbers of contact terminals of the semiconductor device may be varied and applied to a semiconductor device. To shorten descriptions of example embodiments, other elements of a semiconductor device are not illustrated and will not be described.

FIG. 3 is a sectional view illustrating a semiconductor device to be tested according to example embodiments. Referring to FIG. 3, there is provided a semiconductor device 200 to be tested. The semiconductor device 200 may be a semiconductor device package in the form of a fine pitch ball grid array (BGA) or a chip scale package (CSP). The semiconductor device 200 may include a substrate 220, a mold portion 240 including a semiconductor device (not shown) on the substrate 220, and input/output terminals 210a.

The input/output terminals 210a may be electrically connected to the semiconductor substrate, and may be arranged in a lattice configuration on the lower surface of the substrate 220. The input/output terminals 210a may include, for example, solder balls including tin or tin and lead. Contact terminals 110a of a semiconductor device according to example embodiments may be arranged below the input/output terminals 210a. The contact terminals 110a may include, for example, bar-type configurations. The contact terminals 110a contacting the input/output terminals 210a may have one or a plurality of sharp heads to facilitate contact with the input/output terminals 210a. The contact terminals 110a may be, for example, socket pins of a test socket.

To briefly describe a test procedure, the contact terminals 110a may be moved perpendicularly to the lower surface of the substrate 220 so that the contact terminals 110a and the input/output terminals 210a may contact one another. After the contact terminals 110a are contacted, the semiconductor device may apply electrical signals through the contact terminals 110a to the semiconductor device 200. After testing is completed, the contact terminals 110a may be moved apart from the input/output terminals 210a of the semiconductor device 200, after which the semiconductor apparatus 200 is replaced with another semiconductor apparatus 200 to be tested.

FIG. 4 is a sectional view illustrating a semiconductor device to be tested according to example embodiments. Referring to FIG. 4, there is provided a semiconductor device 200a to be tested. The semiconductor device 200a may be a semiconductor device package configured as a ball grid array (BGA). The semiconductor device 200a may include a substrate 220, a mold portion 240 including a semiconductor device (not shown) on the substrate 220, and input/output terminals 210b.

The input/output terminals 210b may be arranged in a lattice configuration on the lower surface of the substrate 220. The input/output terminals 210b may be, for example, solder balls including tin or tin and lead. Depending on the distance between the input/output terminals 210b, the number of contact terminals 110b for each input/output terminal 210b may be 2, 3, or 4. When two contact terminals 110b are used, the contact terminals 110b may be suitable for packages configured as micro ball grid arrays (MBGA) with a relatively small pitch between the input/output terminals 210b. When 3 or 4 contact terminals 110b are used, a more reliable electrical connection may be obtained than when 2 contact terminals 110b are used. However, due to restrictions imposed by the pitch between solder balls, the contact terminals 110b are suitable for a ball grid array (BGA) package configuration having a relatively large pitch between input/output terminals 210b.

According to example embodiments, the contact terminals 110b of the semiconductor device may be arranged on either side of the input/out terminals 210b. Unlike example embodiments illustrated in FIG. 3, the contact terminals 110b may have, for example, bar type configurations, or may have pinch type configurations when one input/output terminal 210b has two contact terminals 110b. The contact terminals 110a contacting the input/output terminals 210b may also have sharp heads to facilitate contact with the input/output terminals 210b.

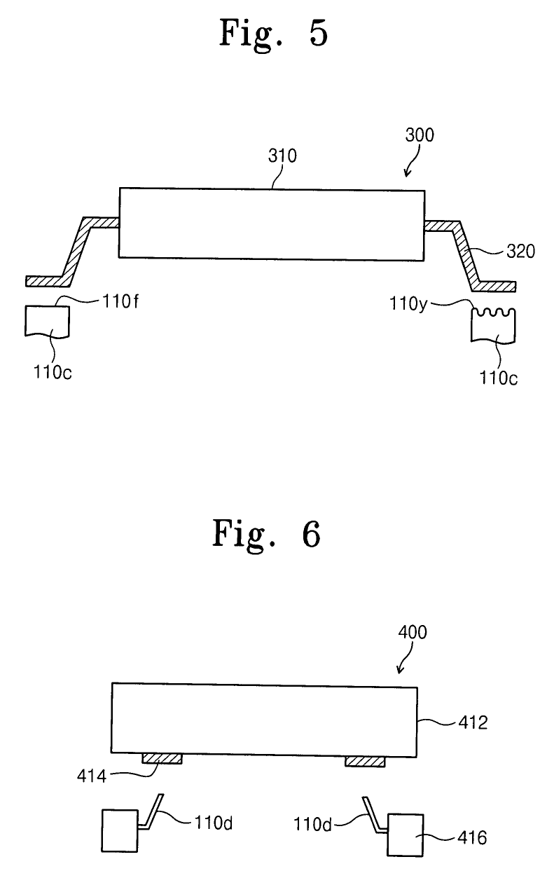

FIG. 5 is a sectional view illustrating a semiconductor device to be tested according to example embodiments. Referring to FIG. 5, there is provided a semiconductor device 300 to be tested. The semiconductor device 300 may be a semiconductor device package configured as a quad flat package (QFP) or a thin small outline package (TSOP). The semiconductor device 300 may include a lead frame portion 310 and an input/output terminal 320.

The input/output terminals 320 may be electrically connected to a semiconductor device within a lead frame 310 and extend through the outside of the lead frame 310. The extending input/output terminal 320 may have a rod type configuration. The input/output terminal 320 may include tin or tin and lead. Unlike in example embodiments illustrated in FIGS. 3 and 4, the contact terminals 110c may have a planarized contact surface 110f or an uneven contact surface 110y to facilitate contact with the input/output terminals 320.

FIG. 6 is a sectional view illustrating a semiconductor device to be tested according to example embodiments. Referring to FIG. 6, there is provided a semiconductor device 400 to be tested. The semiconductor device 400 may include a semiconductor chip 412 and an input/output terminal 414. The semiconductor chip 412 may include a circuit portion (not shown) inside a semiconductor chip.

The input/output terminals 414 may be bonding pads formed along the edges of the semiconductor chip 412 and electrically connected to the circuit portion. The input/output terminals 414 may include, for example, tin or tin and lead. The contact terminals 110d may be probe tips of a probe card for contacting bonding pads, which connect to a tester (not shown) for testing the state of a wafer. There may be a plurality of contact terminals 110d configured to be fixed to mounts 416 corresponding to the input/output terminals 414. The contact terminals 110d may have a cantilevered shape with one end bent at a predetermined or given angle. Unlike in example embodiments illustrated in FIGS. 3-5, example embodiments illustrated in FIG. 6 may be applied to probe tips used for electrical inspection in a wafer state.

According to example embodiments, a higher degree of precision and reliability may be realized during a test procedure. Accordingly, the yield and quality of semiconductor devices may be improved. In addition, maintenance and repair of contact terminals of a semiconductor device may be made easier, so that the service life of the semiconductor device may be extended.

The above-disclosed subject matter is to be considered illustrative, and not restrictive, and the appended claims are intended to cover all such modifications, enhancements, and other embodiments, which fall within the true spirit and scope of example embodiments. Thus, to the maximum extent allowed by law, the scope of example embodiments is to be determined by the broadest permissible interpretation of the following claims and their equivalents, and shall not be restricted or limited by the foregoing detailed description.

1. A semiconductor device, comprising:
a base material; and
a compound layer on the base material including a mixture of a non-adhesive organic material and a non-oxidizing metal material.

2. The semiconductor device of claim 1, wherein the organic material comprises a fluorine resin-based organic material.

3. The semiconductor device of claim 1, wherein the non-oxidizing metal material comprises at least one of gold (Au), silver (Ag), platinum (Pt), palladium (Pd), iridium (Ir), osmium (Os), rhodium (Rh), and ruthenium (Ru).

4. The semiconductor device of claim 2, wherein the organic material comprises at least one of polytetrafluoroethylen (PTFE), a tetrafluorethylen-perfluoralkylvinylether (PFA) copolymer, polyfluorovinyliden (PVDF), polyethylene (PE), polypropylene (PP), polychlorotrifluoroethylene (PCTFE), a tetrafluorethylene-hexafluorpropylene (FEP) copolymer, and an ethylene-tetrafluorethylene (ETFE) copolymer.

5. The semiconductor device of claim 1, wherein
the base material includes a contact region configured to electrically connect to an input/output terminal of a semiconductor device to be tested, and
the compound layer covers the base material in the contact region.

6. The semiconductor device of claim 1, further comprising:
a bonding layer between the base material and the compound layer to bond the base material and the compound layer.

7. The semiconductor device of claim 6, wherein the bonding layer is a nickel plating layer or a copper plating layer.

8. The semiconductor device of claim 1, wherein the base material has a bar-type configuration and includes one or a plurality of sharp heads.

9. The semiconductor device of claim 8, wherein the bar-type configuration comprises a bent bar-type configuration.

10. The semiconductor device of claim 1, wherein the base material comprises a planarized contact surface.

11. The semiconductor device of claim 1, wherein the base material comprises an uneven contact surface.

12. The semiconductor device of claim 1, wherein the base material has a cantilevered shape with one end bent at a given angle.

13-20. (canceled)

21. The semiconductor device of claim 1, wherein the base material comprises at least one of beryllium copper (BeCu), tungsten (W), and ruthenium tungsten (RuW).
